(19) United States
(12) Patent Application Publication
(10) Pub. No.: US 2016/0115313 A1
(43) Pub. Date: Apr. 28, 2016

(54) CYANATE RESIN COMPOSITION AND USE THEREOF

(71) Applicant: SHENGYI TECHNOLOGY CO., LTD., Guangdong (CN)

(72) Inventors: Junqi TANG, Guangdong (CN); Yongjing XU, Guangdong (CN)

(21) Appl. No.: 14/894,789

(22) PCT Filed: May 30, 2013
(86) PCT No.: PCT/CN2013/076498

§ 371 Date: Nov. 30, 2015

(51) Int. Cl. C08L 63/04; C08L 61/14; C08J 5/24; H05K 1/03

(52) U.S. Cl. CPC C08L 63/04; H05K 1/0373; C08L 61/14; C08J 5/24; C08J 2361/14; C08J 2363/04; C08J 2461/14; C08J 2463/04; C08L 2203/20

(57) ABSTRACT

The present invention relates to a cyanate resin composition, and a prepreg, a laminate, a metal foil clad laminate and a printed circuit board prepared by using same. The cyanate resin composition comprises a cyanate resin (A) and an epoxy resin (B) with a structure of formula (I). The cyanate resin composition of the present invention, and the prepreg, the laminate and the metal foil clad laminate prepared by using the cyanate resin composition have good moisture resistance, heat resistance, flame retardancy and reliability, and are suitable for being used as a substrate material for manufacturing a high-density printed circuit board.

### TECHNICAL FIELD

The present invention relates to a resin composition, especially to a cyanate resin composition, as well as a prepreg, a laminate, a metal foil clad laminate and a printed circuit board prepared by using same.

### BACKGROUND ART

With the developments of computers, electronic and information communication equipments in the direction of miniaturization, high performance and high function, higher requirements are put forward for printed circuit boards, i.e. miniaturization, thinning tendency, high integration and high reliability. This requires that the metal foil clad laminates for manufacturing printed circuit boards shall have better moisture resistance, heat resistance and reliability.

Cyanate resins have excellent dielectric property, heat resistance, mechanical property and processability, and are common substrate resin in the metal foil clad laminate for manufacturing high-end printed circuit boards. However, cyanate resins have a worse moisture and heat resistance after self-curing. Thus cyanate resins won't be used unless they are modified by using epoxy resins.

Although current commonly used bisphenol epoxy resins have excellent processability, they are insufficient in heat resistance and moisture resistance. Linear novolac epoxy resins still have disadvantages in moisture resistance and processability though there is improvement in heat resistance.

Additionally, the resin compositions for manufacturing metal foil clad laminates generally need to have flame retardancy, so that the flame retardants containing bromide shall be used to realize flame retardancy. Since there are increasing concerns about environmental issues in recent years, flame retardancy needs to be realized by using no halogen-containing compounds. Thus the resins per se are required to have better flame retardancy.

Although the moisture resistances of phenolphenylaralkyl epoxy resins and phenolnaphthylaralkyl epoxy resins are improved, there are still deficiencies in heat resistance and flame retardancy.

Although the flame retardancies of naphtholbiphenylaralkyl epoxy resins and naphtholnaphthylaralkyl epoxy resins are increased, the processabilities thereof are decreased along with the increase of the melt viscosity of resins thereupon.

### DISCLOSURE OF THE INVENTION

One of the objects of the present invention lies in providing a cyanate resin composition having better moisture resistance, heat resistance, flame retardancy and reliability, as well as better processability.

In order to achieve the object above, the present invention uses the following technical solution:

a cyanate resin composition comprising a cyanate resin (A) and an epoxy resin (B) with a structure of formula (I)

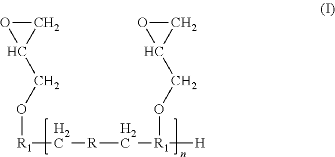

wherein R₁ is selected from the group consisting of phenyl and naphthyl, wherein the molar ratio of naphthyl/(naphthyl+phenyl) ranges from 0.05 to 0.95; R is aryl; n is an integer of 1-20, e.g. 2, 3, 4, 5, 6, 7, 8, 9, 10, 11, 12, 13, 14, 15, 16, 17, 18, and 19.

The molar ratio of naphthyl/(naphthyl+phenyl) is selected from the group consisting of, e.g. 0.08, 0.12, 0.15, 0.21, 0.26, 0.32, 0.38, 0.45, 0.51, 0.56, 0.62, 0.67, 0.71, 0.76, 0.81, 0.88, 0.92, and 0.94.

Preferably, n is an integer of 1-15, preferably 1-10. When n ranges from 1 to 10, the epoxy resin (B) with a structure of formula (I) has a better wettability to substrates.

Preferably, the molar ratio of naphthyl/(naphthyl+phenyl) is from 0.1 to 0.8, preferably from 0.2 to 0.7.

R is selected from the group consisting of phenyl, naphthyl and biphenyl, preferably naphthyl and biphenyl.

Said naphthyl is α-naphthyl or β-naphthyl.

Preferably, the epoxy resin (B) with a structure of formula (I) has a melt viscosity of 1.0 Pa·s or less at 150° C.

The exemplary epoxy resin (B) with a structure of formula (I) of the present invention has the following formula:

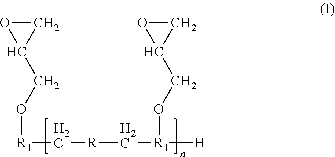

R₁ is selected from the group consisting of phenyl and naphthyl, wherein the molar ratio of naphthyl/(naphthyl+phenyl) ranges from 0.2 to 0.7; R is aryl; n is an integer of 1-10.

The epoxy resin (B) with a structure of formula (I) has a melt viscosity of 1.0 Pa·s or less at 150° C. The epoxy resin (B) with a structure of formula (I) can notably improve the moisture and heat resistance, flame retardancy and processability of cyanate resin compositions.

The inventors found by studies that the combination of a cyanate resin (A) and an epoxy resin (B) with a structure of formula (I) may achieve a resin composition having better moisture resistance, heat resistance, flame retardancy, reliability and processability. The contents of naphthalene ring and benzene ring are controlled within certain ranges in the molecular structure, so as to reduce the melt viscosity of resins and to increase the processability. Due to the rigid structure of the resin skeleton, better heat resistance, moisture resistance, flame retardancy and reliability are maintained. On the basis of the findings above, the inventors achieve the present invention.

The cyanate resin (A) in the present invention is not specifically limited. The cyanate resin (A) in the present invention is selected from the group consisting of cyanates or cyanate prepolymers containing at least two cyanate radicals in the molecular structure thereof, preferably any one or a mixture of at least two selected from the group consisting of bisphenol-A cyanate resin, bisphenol-F cyanate resin, tetramethylbisphenol-F cyanate resin, bisphenol-M cyanate resin, bisphenol-S cyanate resin, bisphenol-E cyanate resin, bisphenol-P cyanate resin, linear novolac cyanate resin, cresol novolac cyanate resin, naphthol cyanate resin, naphthol novolac cyanate resin, dicyclopentadiene cyanate resin, phenothalin cyanate resin, aralkyl cyanate resin, aralkyl novolac cyanate resin, bisphenol-A cyanate prepolymer, bisphenol-F cyanate prepolymer, tetramethylbisphenol-F cyanate prepolymer, bisphenol-M cyanate prepolymer, bisphenol-S cyanate prepolymer, bisphenol-E cyanate prepolymer, bisphenol-P cyanate prepolymer, linear novolac cyanate prepolymer, cresol novolac cyanate prepolymer, naphthol cyanate prepolymer, naphthol novolac cyanate prepolymer, dicyclopentadiene cyanate prepolymer, phenothalin cyanate prepolymer, aralkyl cyanate prepolymer or aralkyl novolac cyanate prepolymer. The mixture above is selected from the group consisting of, e.g. a mixture of bisphenol-A cyanate resin and bisphenol-F cyanate resin, a mixture of tetramethylbisphenol-F cyanate resin and bisphenol-M cyanate resin, a mixture of bisphenol-S cyanate resin and bisphenol-E cyanate resin, a mixture of bisphenol-P cyanate resin and linear novolac cyanate resin, a mixture of cresol novolac cyanate resin and naphthol novolac cyanate resin, a mixture of dicyclopentadiene cyanate resin and phenothalin cyanate resin, a mixture of aralkyl cyanate resin and aralkyl novolac cyanate resin, a mixture of linear novolac cyanate resin and bisphenol-A cyanate prepolymer, a mixture of bisphenol-A cyanate prepolymer and bisphenol-F cyanate prepolymer, a mixture of tetramethylbisphenol-F cyanate prepolymer and bisphenol-M cyanate prepolymer, a mixture of bisphenol-S cyanate prepolymer and bisphenol-E cyanate prepolymer, a mixture of bisphenol-P cyanate prepolymer and linear novolac cyanate prepolymer, a mixture of cresol novolac cyanate prepolymer and naphthol novolac cyanate prepolymer, a mixture of dicyclopentadiene cyanate prepolymer and phenothalin cyanate prepolymer, a mixture of aralkyl cyanate prepolymer and aralkyl novolac cyanate prepolymer. In order to increase the heat resistance and flame retardancy of the cyanate resin composition, the cyanate resin (A) is further preferably any one or a mixture of at least two selected from the group consisting of linear novolac cyanate resin, naphthol cyanate resin, naphthol novolac cyanate resin, phenothalin cyanate resin, aralkyl cyanate resin, aralkyl novolac cyanate resin, linear novolac cyanate prepolymer, naphthol cyanate prepolymer, naphthol novolac cyanate prepolymer, phenothalin cyanate prepolymer, aralkyl cyanate prepolymer or aralkyl novolac cyanate prepolymer. The cyanate resin (A) can be used separately, or in combination as required.

The amount of the cyanate resin (A) is not specifically limited. Preferably, the cyanate resin (A) is in an amount of from 10 to 90% by weight of the total weight of the cyanate resin (A) and epoxy resin (B) with a structure of formula (I), e.g. 12%, 15%, 21%, 26%, 32%, 36%, 45%, 52%, 58%, 63%, 67%, 72%, 77%, 85%, 88%, further preferably from 20 to 80%, specifically preferably from 30 to 70%.

The epoxy resin (B) with a structure of formula (I) can be used separately, or at least two epoxy resins (B) with a structure of formula (I) can be used in combination as required.

The amount of the epoxy resin (B) with a structure of formula (I) is not specifically limited. Preferably, the epoxy resin (B) with a structure of formula (I) is in an amount of from 10 to 90% by weight of the total weight of the cyanate resin (A) and epoxy resin (B) with a structure of formula (I), e.g. 12%, 15%, 21%, 26%, 32%, 36%, 45%, 52%, 58%, 63%, 67%, 72%, 77%, 85%, 88%, further preferably from 20 to 80%, specifically preferably from 30 to 70%.

The process for synthesizing the epoxy resin (B) with a structure of formula (I) is not specifically limited, and those skilled in the art can choose according to existing technology in combination with professional knowledge. Specifically, the epoxy resin (B) with a structure of formula (I), for example, can be obtained by the following method: in the presence of alkaline compounds, aralkyl novolac resin of the formula (II) reacts with epichlorohydrin in an inert organic solvent to obtain the epoxy resin (B) with a structure of formula (I)

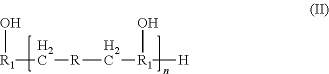

wherein R₁ is selected from the group consisting of phenyl and naphthyl, wherein the molar ratio of naphthyl/(naphthyl+phenyl) ranges from 0.05 to 0.95; R is aryl; n is an integer of 1-20.

The cyanate resin composition further comprises an inorganic filler (C). By adding an inorganic filler (C) into the cyanate resin composition, halogen-free flame retardant composition having better flame retardancy can be obtained. The inorganic filler (C) of the present invention is not specifically limited. The inorganic filler (C) is one or a mixture of at least two selected from the group consisting of silicon dioxide, metal hydrate, molybdenum oxide, zinc molybdate, titania, zinc oxide, strontium titanate, barium titanate, barium sulfate, boron nitride, aluminium nitride, silicon carbide, alumina, zinc borate, zinc stannate, clay, kaolin, talc, mica, composite silica micro-powder, E-glass powder, D-glass powder, L-glass powder, M-glass powder, S-glass powder, T-glass powder, NE-glass powder, quartz glass powder, short glass fiber or hollow glass, preferably any one or a mixture of at least two selected from the group consisting of crystalline silicon dioxide, fused silicon dioxide, amorphous silicon dioxide, spherical silicon dioxide, hollow silicon dioxide, aluminium hydroxide, boehmite, magnesium hydroxide, molybdenum oxide, zinc molybdate, titania, zinc oxide, strontium titanate, barium titanate, barium sulfate, boron nitride, aluminium nitride, silicon carbide, alumina, zinc borate, zinc stannate, clay, kaolin, talc, mica, composite micro silica powder, E-glass powder, D-glass powder, L-glass powder, M-glass powder, S-glass powder, T-glass powder, NE-glass powder, quartz glass powder, short glass fiber or hollow glass. The mixture is selected from the group consisting of, e.g. a mixture of crystalline silicon dioxide and fused silicon dioxide, a mixture of amorphous silicon dioxide and spherical silicon dioxide, a mixture of hollow silicon dioxide and aluminium hydroxide, a mixture of boehmite and magnesium hydroxide, a mixture of molybdenum oxide and zinc molybdate, a mixture of titania, zinc oxide, strontium titanate and barium titanate, a mixture of barium sulfate, boron nitride and aluminium nitride, a mixture of silicon carbide, alumina, zinc borate and zinc stannate, a mixture of composite silica micro-powder, E-glass powder, D-glass powder, L-glass powder and M-glass powder, a mixture of S-glass powder, T-glass powder, NE-glass powder and quartz glass powder, a mixture of clay, kaolin, talc and mica, a mixture of short glass fiber and hollow glass, further preferably fused silicon dioxide or/and boehmite. Fused silicon dioxide has a low coefficient of thermal expansion, and boehmite has excellent flame retardancy and heat resistance, so that they are preferable.

The average particle size (d50) of the inorganic filler (C) is not specifically limited. In consideration of dispersibility, the inorganic filler (C) has an average particle size (d50) ranging from 0.1 to 10 μm, e.g. 0.2 μm, 0.8 μm, 1.5 μm, 2.1 μm, 2.6 μm, 3.5 μm, 4.5 μm, 5.2 μm, 5.5 μm, 6 μm, 6.5 μm, 7 μm, 7.5 μm, 8 μm, 8.5 μm, 9 μm, 9.5 μm, preferably from 0.2 to 5 μm. As required, different types of inorganic fillers (C) having different particle distributions or different average particle sizes can be used separately or in combination.

The amount of the inorganic filler (C) is not specifically limited. Preferably, the inorganic filler (C) is in an amount of from 10 to 300 parts by weight, e.g. 20 parts by weight, 40 parts by weight, 60 parts by weight, 80 parts by weight, 100 parts by weight, 120 parts by weight, 140 parts by weight, 160 parts by weight, 180 parts by weight, 200 parts by weight, 220 parts by weight, 240 parts by weight, 260 parts by weight, 280 parts by weight and 290 parts by weight, preferably from 30-200 parts by weight, further preferably from 50 to 150 parts by weight, based on 100 parts by weight of the total weight of the cyanate resin (A) and the epoxy resin (B) with a structure of formula (I).

The inorganic filler (C) of the present invention can be used together with surfactants, humectants or dispersants. There is no specific definition for surfactants, and surfactants are selected from the common surfactants used for surface treatments of inorganic substances, specifically tetraethylorthosilicate compounds, organic acid compounds, aluminic acid ester compounds, titanate compounds, organosilicon oligomers, macromolecular treating agents, silane coupling agents and the like. Silane coupling agents are not specifically limited, and they are selected from the group consisting of silane coupling agents commonly used for surface treatments of inorganic substances, specifically amino silane coupling agents, epoxy silane coupling agents, ethylene silane coupling agents, phenyl silane coupling agents, cation silane coupling agents, thiol silane coupling agents and the like. Humectants or dispersants are not specifically limited, and they are selected from humectants or dispersants commonly used for coatings. As required, different types of humectants or dispersants can be used separately or in combination.

The cyanate resin composition of the present invention may further comprise an organic filler (D). The organic filler (D) is not specifically limited, and it is any one or a mixture of at least two selected from the group consisting of organosilicon, liquid crystal polymer, thermosetting resin, thermoplastic resin, rubber and core-shell rubber, further preferably from the group consisting of organosilicon powder or/and core-shell rubber. The organic filler (D) can be in the form of powder or particle, wherein organic silicon powder has better flame retardant property, and the core-shell rubber has better toughening effect, so that they are preferable.

The amount of the organic filler (D) is not specifically limited. Preferably, the inorganic filler (D) is in an amount of from 1 to 30 parts by weight, e.g. 2 parts by weight, 5 parts by weight, 7 parts by weight, 9 parts by weight, 12 parts by weight, 15 parts by weight, 18 parts by weight, 21 part by weight, 24 parts by weight, 27 parts by weight, 29 parts by weight, preferably from 3 to 25 parts by weight, further preferably from 5 to 20 parts by weight, based on 100 parts by weight of the total weight of the cyanate resin (A) and the epoxy resin (B) with a structure of formula (I).

The wordings “comprise(s)” “comprising” in the present invention mean that, besides said components, there may be other components which endow the resin composition with different properties. In addition, the wordings “comprise(s)” “comprising” in the present invention may be replaced with “is/are” or “consist(s) of” in a closed manner.

The cyanate resin composition of the present invention can be used together with other epoxy resins than the epoxy resin (B) with a structure of formula (I), as long as said other epoxy resins do not impair the intrinsic properties of the cyanate resin composition. Said other epoxy resins are selected from the group consisting of bisphenol A epoxy resin, bisphenol F epoxy resin, linear novolac epoxy resin, cresol novolac epoxy resin, bisphenol A novolac epoxy resin, tetramethylbisphenol F epoxy resin, bisphenol M epoxy resin, bisphenol S epoxy resin, bisphenol E epoxy resin, bisphenol P epoxy resin, trifunctional phenol epoxy resin, tetrafunctional phenol epoxy resin, naphthalene epoxy resin, naphthol epoxy resin, naphthol novolac epoxy resin, anthracene epoxy resin, phenoxy epoxy resin, norbornene epoxy resin, adamantane epoxy resin, fluorene epoxy resin, biphenyl epoxy resin, dicyclopentadiene epoxy resin, aralkyl epoxy resin, aralkyl novolac epoxy resin, epoxy resin containing an arylene ether structure in the molecular thereof, cycloaliphatic epoxy resin, polyol epoxy resin, silicon-containing epoxy resin, nitrogen-containing epoxy resin, phosphorus-containing epoxy resin, glycidyl amine epoxy resin, glycidyl ester epoxy resin and the like. These epoxy resins can be used separately or in combination as required.

The cyanate resin composition of the present invention can also be used in combination with various polymers, specifically for example, liquid crystal polymers, thermosetting resins, thermoplastic resins, different flame retardant compounds or additives, as long as the intrinsic properties of the cyanate resin composition will not be damaged thereby. They can be used separately or in combination as required.

The cyanate resin composition of the present invention can be used together with curing accelerators as required, so as to control the curing reaction rate. The curing accelerator is not specifically limited, and it is selected from the curing accelerators for promoting the curing of the cyanate resins and epoxy resins, specifically organic salts of the metals, such as copper, zinc, cobalt, nickel, manganese and the like, imidazoles and derivatives thereof, tertiary amines and the like.

In addition, the cyanate resin composition may comprise various additives, specifically for example, antioxidants, heat stabilizers, antistatic agents, ultraviolet light absorbers, pigments, colorants, lubricants and the like.

As the process for preparing one of the resin compositions of the present invention, the composition can be prepared by formulating, stirring and mixing the epoxy resin (B) with a structure of formula (I) and the cyanate resin (A) according to known methods.

Another object of the present invention is to provide a prepreg, a laminate, a metal foil clad laminate and a printed circuit board. The laminate and the metal foil clad laminate prepared by using the prepreg have good moisture resistance, heat resistance, flame retardancy, reliability, as well as better processability, and are suitable for being used as a substrate material for manufacturing a high-density printed circuit board.

The present invention provides a prepreg prepared by using the aforesaid cyanate resin composition, wherein the prepreg comprises a substrate material and the aforesaid cyanate resin composition attached on the substrate material after impregnation and drying. The substrate material of the present invention is not specifically limited, and it is selected from known substrate materials for manufacturing various printed circuit board materials, specifically inorganic fibers (e.g. glass fibers, such as E-glass, D-glass, L-glass, M-glass, S-glass, T-glass, NE-glass, quartz and the like), organic fibers (e.g. polyimide, polyamide, polyester, polyphenyl ether, liquid crystal polymer and the like). Generally, the substrate material is in a form of textiles, non-woven fabrics, rough yarns, short fibers, fiber paper and the like. Among said substrate materials, the glass fiber cloth is preferable for the substrate material of the present invention.

There is no specific definition for the process for preparing the prepreg of the present invention, as long as it is related to the process for preparing the prepreg by combining the cyanate resin composition with the substrate material of the present invention.

An organic solvent can be used as required in the cyanate resin composition for preparing the prepreg. There is no specific definition for the organic solvent, as long as it is a solvent compatible with the mixture of the epoxy resin (B) with a structure of formula (I) and the cyanate resin (A). The solvent is selected from the group consisting of, for example, alcohols, such as methanol, ethanol, butanol and the like, ethyl cellosolve, butyl cellosolve, ethers, such as glycol methyl ether, diethylene glycol ether, diethylene glycol butyl ether and the like, ketones such as acetone, butanone, methylethylketone, methylisobutylketone, cyclohexanone and the like, aromatic hydrocarbons such as toluene, xylol, mesitylene and the like, esters such as ethoxyethyl acetate, ethyl acetate and the like, nitrogen-containing solvents such as N,N-dimethylformamide, N,N-dimethylacetamide, N-methyl-2-pyrrolidone. The aforesaid solvents can be used separately, or in combination as required.

The present invention further provides a laminate and a metal foil clad laminate prepared by using the prepreg. The laminate comprises at least one prepreg above, and is obtained by laminating and curing overlapped prepregs. The metal foil clad laminate comprises at least one prepreg as stated above and metal foils coated on one or both sides of the prepreg. Coating the metal foils onto one or both sides of the overlapped prepregs to obtain the metal foil clad laminate by lamination and curing. The laminate and metal foil clad laminate prepared by using such prepreg have good moisture resistance, heat resistance, flame retardancy, reliability, as well as better processability, and are suitable for being used as a substrate material for manufacturing a high-density printed circuit board.

The laminate of the present invention can be prepared by known methods. For example, one sheet of the prepreg is placed, or two or more sheets of the prepreg are stacked. The metal foil is placed onto one or both sides of the prepreg or the stacked prepregs, laminated and cured to obtain the laminate or metal foil clad laminate. The metal foil is not specifically limited, and is selected from the group consisting of the metal foils used for the printed circuit board materials. The lamination can be carried out under the general lamination conditions for the laminate and composite board used for the printed circuit board.

The present invention further provides a printed circuit board comprising at least one prepreg above. The printed circuit board of the present invention is not specifically limited, and it can be prepared by known methods.

The present invention has the following beneficial effects. The cyanate resin composition of the present invention has good moisture resistance, heat resistance, flame retardancy, reliability, as well as better processability. The laminate and metal foil clad laminate prepared by using the cyanate resin composition also have good moisture resistance, heat resistance, flame retardancy, reliability, as well as better processability, and are suitable for being used as a substrate material for manufacturing a high-density printed circuit board.

### Embodiments

In order to better explain the present invention and to understand the technical solution of the present invention, the present invention provides the following typical, but non-restrictive examples.

As for the metal foil clad laminate prepared from the cyanate resin composition of the present invention, Tg, solder dipping resistance, moisture and heat resistance and flame retardancy thereof are tested. The test results are further explained and described by the following examples.

### SYNTHESIS EXAMPLE 1

### Synthesis of Naphthylaralkyl Novolac Resin

46 g of β-naphthol, 271 g of phenol, 215 g of dichloromethylnaphthalene and 300 g of chlorobenzene were added to a flask. Protected by nitrogen, the mixture was stirred, slowly heated and dissolved, reacted for 2 hours at about 80° C. Then, the mixture was heated to 180° C. while distilling chlorobenzene, and reacted for 1 hour at 180° C. After reaction, the solvent and unreacted monomers were removed by reduced pressure distillation to obtain brown naphthylaralkyl novolac resin. By analyzing the recovered unreacted monomers, it could be seen that the molar ratio of β-naphthol/(β-naphthol+phenol) into the resin was 0.23.

### SYNTHESIS EXAMPLE 2

### Synthesis of Naphthylaralkyl Novolac Resin

96 g of β-naphthol, 251 g of phenol, 150 g of dichloromethylnaphthalene and 450g of chlorobenzene were added to a flask. Protected by nitrogen, the mixture was stirred, slowly heated and dissolved, reacted for 2 hours at about 80° C. Then, the mixture was heated to 180° C. while distilling chlorobenzene, and reacted for 1 hour at 180° C. After reaction, the solvent and unreacted monomers were removed by reduced pressure distillation to obtain brown naphthylaralkyl novolac resin. By analyzing the recovered unreacted monomers, it could be seen that the molar ratio of β-naphthol/(β-naphthol+phenol) into the resin was 0.50.

### SYNTHESES EXAMPLE 3

### Synthesis of Naphthylaralkyl Novolac Resin

224 g of β-naphthol, 272 g of phenol, 100 g of dichloromethylnaphthalene and 300g of chlorobenzene were added to a flask. Protected by nitrogen, the mixture was stirred, slowly heated and dissolved, reacted for 2 hours at about 80° C. Then, the mixture was heated to 180° C. while distilling chlorobenzene, and reacted for 1 hour at 180° C. After reaction, the solvent and unreacted monomers were removed by reduced pressure distillation to obtain brown naphthylaralkyl novolac resin. By analyzing the recovered unreacted monomers, it could be seen that the molar ratio of β-naphthol/(β-naphthol+phenol) into the resin was 0.70.

### SYNTHESIS EXAMPLE 4

### Synthesis of Naphthylaralkyl Novolac Epoxy Resin

100 g of naphthylaralkyl novolac resin obtained in Synthesis Example 1 was dissolved in 307 g of epichlorohydrin and 48 g of diethylene glycol dimethyl ether. 40 g of 48% sodium hydroxide aqueous solution was dripped for 4 hours at a reduced pressure and 60° C. Water generated during such period was removed from the system by azeotropy with epichlorohydrin, and the distilled epichlorohydrin went back to the system. After dripping, the reaction continued for 1 h. Then epichlorohydrin and diethylene glycol dimethyl ether were removed by reduced pressure distillation, and 295 g of methyl isobutyl ketone was added, stirred and homogeneously dissolved. The produced salts were removed by water washing. 9 g of 48% sodium hydroxide aqueous solution was added and reacted for 2 hour at 80° C. After reaction, water washing was carried out till the washing solution was neutral. Methyl isobutyl ketone was removed by reduced pressure distillation to obtain naphthylaralkyl novolac epoxy resin having a melt viscosity of 0.4 Pa·s at 150° C.

### SYNTHESIS EXAMPLE 5

### Synthesis of Naphthylaralkyl Novolac Epoxy Resin

100 g of naphthylaralkyl novolac resin obtained in Synthesis Example 2 was dissolved in 298 g of epichlorohydrin and 45 g of diethylene glycol dimethyl ether. 38 g of 48% sodium hydroxide aqueous solution was dripped for 4 hours at a reduced pressure and 60° C. Water generated during such period was removed from the system by azeotropy with epichlorohydrin, and the distilled epichlorohydrin went back to the system. After dripping, the reaction continued for 1 h. Then epichlorohydrin and diethylene glycol dimethyl ether were removed by reduced pressure distillation, and 295 g of methyl isobutyl ketone was added, stirred and homogeneously dissolved. The produced salts were removed by water washing. 9 g of 48% sodium hydroxide aqueous solution was added and reacted for 2 hour at 80° C. After reaction, water washing was carried out till the washing solution was neutral. Methyl isobutyl ketone was removed by reduced pressure distillation to obtain naphthylaralkyl novolac epoxy resin having a melt viscosity of 0.5 Pa·s at 150° C.

### SYNTHESIS EXAMPLE 6

### Synthesis of Naphthylaralkyl Novolac Epoxy Resin

100 g of naphthylaralkyl novolac resin obtained in Synthesis Example 3 was dissolved in 300 g of epichlorohydrin and 45 g of diethylene glycol dimethyl ether. 38.5 g of 48% sodium hydroxide aqueous solution was dripped for 4 hours at a reduced pressure and 60° C. Water generated during such period was removed from the system by azeotropy with epichlorohydrin, and the distilled epichlorohydrin went back to the system. After dripping, the reaction continued for 1 h. Then epichlorohydrin and diethylene glycol dimethyl ether were removed by reduced pressure distillation, and 295 g of methyl isobutyl ketone was added, stirred and homogeneously dissolved. The produced salts were removed by water washing. 9 g of 48% sodium hydroxide aqueous solution was added and reacted for 2 hour at 80° C. After reaction, water washing was carried out till the washing solution was neutral. Methyl isobutyl ketone was removed by reduced pressure distillation to obtain naphthylaralkyl novolac epoxy resin having a melt viscosity of 0.6 Pa·s at 150° C.

### EXAMPLE 1

30 parts by weight of linear novolac cyanate resin (PT-30, provided by LONZA), 70 parts by weight of naphthylaralkyl novolac epoxy resin obtained in Synthesis Example 6 and 0.02 parts by weight of zinc caprylate were dissolved in butanone and homogeneously mixed. Then 150 parts by weight of boehmite (APYRAL AOH 30, provided by Nabaltec), 1.5 parts by weight of epoxy silane coupling agent (Z-6040, provided by Dow Corning) and 1 part by weight of dispersant (BYK-W903, provided by BYK) were added and adjusted to a suitable viscosity with butanone. The mixture was stirred and mixed homogeneously to obtain a glue solution. E-glass fiber cloth having a thickness of 0.1 mm was impregnated with said glue solution, oven-dried to remove solvent, so as to obtain a prepreg. 4 sheets and 8 sheets of the prepreg above were stacked up separately. Both sides of each of them were pressed with electrolytic copper foil having a thickness of 18 μm, cured for 2 hours in a pressing machine at a curing pressure of 45 Kg/cm² and a curing temperature of 220° C., to obtain a copper clad laminate having a thickness of 0.4 mm or 0.8 mm.

### EXAMPLE 2

50 parts by weight of α-naphtholaralkyl cyanate resin (obtained by reacting α-naphthylaralkyl resin SN485 provided by NIPPON STEEL & SUMITOMO METAL with cyanogen chloride), 45 parts by weight of naphthylaralkyl novolac epoxy resin obtained in Synthesis Example 6, 5 parts by weight of naphthylene ether naphthol epoxy resin (EXA-7311, provided by DIC) and 0.02 parts by weight of zinc caprylate were dissolved in butanone and homogeneously mixed. Then 110 parts by weight of spherical fused silicon dioxide (SC2050, provided by Admatechs), 5 parts by weight of organosilicon powder having a core-shell structure (KMP-605, provided by

Shin-Etsu Chemical Co., Ltd.) and 1 part by weight of epoxy silane coupling agent (Z-6040, provided by Dow Corning) were added and adjusted to a suitable viscosity with butanone. The mixture was stirred and mixed homogeneously to obtain a glue solution. According to the same preparing process as Example 1, copper clad laminate having a thicknesses of 0.4 or 0.8 mm was obtained.

### EXAMPLE 3

10 parts by weight of naphthol novolac cyanate resin (obtained according to the method provided in Synthesis Example 2 of CN102911502A), 45 parts by weight of α-naphtholaralkyl cyanate resin (obtained by reacting α-naphtholaralkyl resin SN485 provided by NIPPON STEEL & SUMITOMO METAL with cyanogen chloride), 5 parts by weight of naphthyl aralkyl novolac epoxy resin obtained in Synthesis Example 4, 40 parts by weight of naphthylaralkyl novolac epoxy resin obtained in Synthesis Example 5, and 0.02 parts by weight of zinc caprylate were dissolved in butanone and homogeneously mixed. Then 50 parts by weight of spherical fused silicon dioxide (SC2050, provided by Admatechs), 70 parts by weight of boehmite (APYRAL AOH 30, provided by Nabaltec), 10 parts by weight of organosilicon powder (KW-590, provided by Shin-Etsu Chemical Co., Ltd.), 5 parts by weight of organosilicon powder having a core-shell structure (KMP-605, provided by Shin-Etsu Chemical Co., Ltd.), 1 part by weight of epoxy silane coupling agent (Z-6040, provided by Dow Corning) and 1 part by weight of dispersant (BYK-W903, provided by BYK) were added and adjusted to a suitable viscosity with butanone. The mixture was stirred and mixed homogeneously to obtain a glue solution. According to the same preparing process as Example 1, copper clad laminate having a thicknesses of 0.4 or 0.8 mm was obtained.

### EXAMPLE 4

70 parts by weight of α-naphtholaralkyl cyanate resin (obtained by reacting α-naphtholaralkyl resin SN485 provided by NIPPON STEEL & SUMITOMO METAL with cyanogen chloride), 20 parts by weight of naphthylaralkyl novolac epoxy resin obtained in Synthesis Example 6, 10 parts by weight of phenolbiphenylaralkyl epoxy resin (NC-3000-FH, provided by Nippon Kayaku Co., Ltd.), and 0.02 parts by weight of zinc caprylate were dissolved in butanone and homogeneously mixed. Then 60 parts by weight of boehmite (APYRAL AOH 30, provided by Nabaltec), 20 parts by weight of organosilicon powder (KW-590, provided by Shin-Etsu Chemical Co., Ltd.) and 1 part by weight of epoxy silane coupling agent (Z-6040, provided by Dow Corning) and 1 part by weight of dispersant (BYK-W903, provided by BYK) were added and adjusted to a suitable viscosity with butanone. The mixture was stirred and mixed homogeneously to obtain a glue solution. According to the same preparing process as Example 1, copper clad laminate having a thicknesses of 0.4 or 0.8 mm was obtained.

### EXAMPLE 5

25 parts by weight of linear novolac cyanate resin (PT-30, provided by LONZA), 75 parts by weight of naphthylaralkyl novolac epoxy resin obtained in Synthesis Example 4 and 0.02 parts by weight of zinc caprylate were dissolved in butanone and homogeneously mixed. Then 220 parts by weight of spherical fused silicon dioxide (SC2050, provided by Admatechs), 1.5 parts by weight of epoxy silane coupling agent (Z-6040, provided by Dow Corning) and 1 part by weight of dispersant (BYK-W903, provided by BYK) were added and adjusted to a suitable viscosity with butanone. The mixture was stirred and mixed homogeneously to obtain a glue solution. According to the same preparing process as Example 1, copper clad laminate having a thicknesses of 0.4 or 0.8 mm was obtained.

### EXAMPLE 6

70 parts by weight of α-naphtholaralkyl cyanate resin (obtained by reacting α-naphtholaralkyl resin SN485 provided by NIPPON STEEL & SUMITOMO METAL with cyanogen chloride), 30 parts by weight of naphthylaralkyl novolac epoxy resin obtained in Synthesis Example 6 and 0.02 parts by weight of zinc caprylate were dissolved in butanone and homogeneously mixed. Then 15 parts by weight of spherical fused silicon dioxide (SC2050, provided by Admatechs), 30 parts by weight of organosilicon powder (KW-590, provided by Shin-Etsu Chemical Co., Ltd.) and 1 part by weight of epoxy silane coupling agent (Z-6040, provided by Dow Corning) were added and adjusted to a suitable viscosity with butanone. The mixture was stirred and mixed homogeneously to obtain a glue solution. According to the same preparing process as Example 1, copper clad laminate having a thicknesses of 0.4 or 0.8 mm was obtained.

### COMPARISON EXAMPLE 1

Copper clad laminate having a thicknesses of 0.4 or 0.8 mm was obtained according to the method as stated in Example 1, except that 70 parts by weight of naphthylaralkyl novolac epoxy resin in Example 1 was replaced with 70 parts by weight of bisphenol A epoxy resin (EPICLON® 1055, provided by DIC).

### COMPARISON EXAMPLE 2

Copper clad laminate having a thicknesses of 0.4 or 0.8 mm was obtained according to the method as stated in Example 2, except that 45 parts by weight of naphthylaralkyl novolac epoxy resin in Example 2 was replaced with 45 parts by weight of phenolphenylaralkyl epoxy resin (NC-2000, provided by Nippon Kayaku Co., Ltd.).

### COMPARISON EXAMPLE 3

Copper clad laminate having a thicknesses of 0.4 or 0.8 mm was obtained according to the method as stated in Example 6, except that 30 parts by weight of naphthylaralkyl novolac epoxy resin in Example 6 was replaced with 30 parts by weight of bisphenol A epoxy resin (EPICLON® 1055, provided by DIC).

The test data of the physical properties of copper clad laminates prepared according to Examples 1-6 and Comparison Examples 1-3 are listed in Tables 1 and 2.

TABLE 1
Test data of the physical properties of copper clad laminates prepared according to
Examples 1-6

| | Example 1 | Example 2 | Example 3 | Example 4 | Example 5 | Example 6 |
|---|---|---|---|---|---|---|
| Tg, ° C. | 245 | 245 | 250 | 260 | 240 | 260 |
| Solder Dipping | >120 | >120 | >120 | >120 | >120 | >120 |
| Resistance 288° C., S | | | | | | |
| Moisture and | 0/3 | 0/3 | 0/3 | 0/3 | 0/3 | 0/3 |
| Heat Resistance | | | | | | |
| Flame | V-0 | V-0 | V-0 | V-0 | V-0 | V-1 |
| Retardancy | | | | | | |

TABLE 2
Test data of the physical properties of copper clad laminates
prepared according to Comparison Examples 1-3

| | Comparison | Comparison | Comparison |
|---|---|---|---|
| | Example 1 | Example 2 | Example 3 |
| Tg, ° C. | 210 | 220 | 230 |
| Solder Dipping Resistance | >120 | >120 | >120 |
| 288° C., S | | | |
| Moisture and Heat | 3/3 | 0/3 | 3/3 |
| Resistance | | | |
| Flame Retardancy | combusting | V-1 | combusting |

The physical properties of copper clad laminates in Tables 1 and 2 were tested according to the methods as follows.

Tg: testing apparatus and conditions: DMA, temperature increasing rate of 5° C./min; the samples to be tested having the following specifications: having etched copper foils away, 0.8 mm.

Solder Dipping Resistance: dipping a sample of 50×50 mm in a tin stove at 288° C. to observe delamination and blistering and to record corresponding time; the samples to be tested having the following specifications: with copper foils, 0.4 mm.

Flame Retardancy: testing according to the standard of UL94 vertical flame test; the samples to be tested having the following specifications: having etched copper foils away, 0.4 mm.

Moisture and Heat Resistance: drying a sample of 50×50 mm at 105° C. for 2 hours; treating the sample in a high pressure cooking test machine at 121° C. and an atmospheric pressure of 2 for 3 hours; then tin dipping the sample in a tin stove at 260° C. for 60 seconds to observe whether the sample is delaminated (the number of delaminated samples/the number of the samples to be tested); the samples to be tested having the following specifications: having etched copper foils away, 0.4 mm.

Analyses of the Physical Properties

By comparing the Examples with Comparison Examples, it can be seen that the heat resistance, moisture resistance and flame retardancy of Examples 1-6 above all are superior to Comparison Examples 1 and 3 using bisphenol A epoxy resin; and the heat resistance and flame retardancy of Examples 1-5 above all are superior to Comparison Example 2 using phenolphenylaralkyl epoxy resin.

In conclusion, the cyanate resin composition of the present invention, and the prepreg, the laminate and the metal foil clad laminate prepared by using the cyanate resin composition of the present invention have good moisture resistance, heat resistance, flame retardancy and reliability, and are suitable for being used as a substrate material for manufacturing a high-density printed circuit board.

The aforesaid examples are not limitations to the amounts of the components of the present composition. Any tiny amendment, equivalent change or modification to the aforesaid examples on the basis of the technical essence, the weight parts or amounts of the components of the composition, still falls within the scope of the technical solution of the present invention.

The applicant declares that, the present invention detailedly discloses the composition of the present invention by the aforesaid examples, but the present invention is not limited by the detailed composition, i.e. it does not mean that the present invention cannot be fulfilled unless the aforesaid detailed composition is used. Those skilled in the art shall know that, any amendment, equivalent change to the product materials of the present invention, addition of auxiliary ingredients, and selection of any specific modes all fall within the protection scope and disclosure scope of the present invention.

1. A cyanate resin composition, characterized in that the cyanate resin composition comprises a cyanate resin (A) and an epoxy resin (B) with a structure of formula (I) 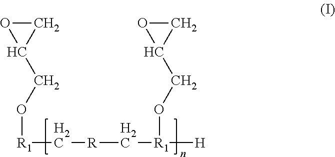
wherein R₁ is selected from the group consisting of phenyl and naphthyl, and the molar ratio of naphthyl/(naphthyl+phenyl) ranges from 0.05 to 0.95; R is aryl; n is an integer of 1-20.

2. (canceled)

3. (canceled)

4. (canceled)

5. (canceled)

6. (canceled)

7. (canceled)

8. (canceled)

9. (canceled)

10. (canceled)

11. The cyanate resin composition as claimed in claim 1, characterized in that n in the epoxy resin (B) with a structure of formula (I) is an integer of 1-10.

12. The cyanate resin composition as claimed in claim 1, characterized in that the molar ratio of naphthyl/(naphthyl+phenyl) ranges from 0.1 to 0.8.

13. The cyanate resin composition as claimed in claim 1, characterized in that R is selected from the group consisting of phenyl, naphthyl and biphenyl.

14. The cyanate resin composition as claimed in claim 1, characterized in that the epoxy resin (B) with a structure of formula (I) has a melt viscosity of 1.0 Pa·s or less at 150° C.

15. The cyanate resin composition as claimed in claim 1, characterized in that the cyanate resin (A) is selected from the group consisting of cyanates or cyanate prepolymers containing at least two cyanate radicals in the molecular structure thereof.

16. The cyanate resin composition as claimed in claim 1, characterized in that the cyanate resin (A) is any one or a mixture of at least two selected from the group consisting of bisphenol-A cyanate resin, bisphenol-F cyanate resin, tetramethylbisphenol-F cyanate resin, bisphenol-M cyanate resin, bisphenol-S cyanate resin, bisphenol-E cyanate resin, bisphenol-P cyanate resin, linear novolac cyanate resin, cresol novolac cyanate resin, naphthol cyanate resin, naphthol novolac cyanate resin, dicyclopentadiene cyanate resin, phenothalin cyanate resin, aralkyl cyanate resin, aralkyl novolac cyanate resin, bisphenol-A cyanate prepolymer, bisphenol-F cyanate prepolymer, tetramethylbisphenol-F cyanate prepolymer, bisphenol-M cyanate prepolymer, bisphenol-S cyanate prepolymer, bisphenol-E cyanate prepolymer, bisphenol-P cyanate prepolymer, linear novolac cyanate prepolymer, cresol novolac cyanate prepolymer, naphthol cyanate prepolymer, naphthol novolac cyanate prepolymer, dicyclopentadiene cyanate prepolymer, phenothalin cyanate prepolymer, aralkyl cyanate prepolymer or aralkyl novolac cyanate prepolymer.

17. The cyanate resin composition as claimed in claim 1, characterized in that the cyanate resin (A) is any one or a mixture of at least two selected from the group consisting of linear novolac cyanate resin, naphthol cyanate resin, naphthol novolac cyanate resin, phenothalin cyanate resin, aralkyl cyanate resin, aralkyl novolac cyanate resin, linear novolac cyanate prepolymer, naphthol cyanate prepolymer, naphthol novolac cyanate prepolymer, phenothalin cyanate prepolymer, aralkyl cyanate prepolymer or aralkyl novolac cyanate prepolymer.

18. The cyanate resin composition as claimed in claim 1, characterized in that the cyanate resin (A) is from 10 to 90% by weight of the total weight of the cyanate resin (A) and the epoxy resin (B) with a structure of formula (I).

19. The cyanate resin composition as claimed in claim 1, characterized in that the epoxy resin (B) with a structure of formula (I) is from 10 to 90% by weight of the total weight of the cyanate resin (A) and the epoxy resin (B) with a structure of formula (I).

20. The cyanate resin composition as claimed in claim 1, characterized in that the cyanate resin composition further comprises an inorganic filler (C).

21. The cyanate resin composition as claimed in claim 20, characterized in that the inorganic filler (C) is any one or a mixture of at least two selected from the group consisting of silicon dioxide, metal hydrate, molybdenum oxide, zinc molybdate, titania, zinc oxide, strontium titanate, barium titanate, barium sulfate, boron nitride, aluminium nitride, silicon carbide, alumina, zinc borate, zinc stannate, clay, kaolin, talc, mica, composite silica micro-powder, E-glass powder, D-glass powder, L-glass powder, M-glass powder, S-glass powder, T-glass powder, NE-glass powder, quartz glass powder, short glass fiber or hollow glass.

22. The cyanate resin composition as claimed in claim 20, characterized in that the inorganic filler (C) is any one or a mixture of at least two selected from the group consisting of crystalline silicon dioxide, fused silicon dioxide, amorphous silicon dioxide, spherical silicon dioxide, hollow silicon dioxide, aluminium hydroxide, boehmite, magnesium hydroxide, molybdenum oxide, zinc molybdate, titania, zinc oxide, strontium titanate, barium titanate, barium sulfate, boron nitride, aluminium nitride, silicon carbide, alumina, zinc borate, zinc stannate, clay, kaolin, talc, mica, composite silica micro-powder, E-glass powder, D-glass powder, L-glass powder, M-glass powder, S-glass powder, T-glass powder, NE-glass powder, quartz glass powder, short glass fiber or hollow glass.

23. The cyanate resin composition as claimed in claim 20, characterized in that the inorganic filler (C) has an average particle size (d50) ranging from 0.1 to 10 μm.

24. The cyanate resin composition as claimed in claim 20, characterized in that, the inorganic filler (C) is in an amount of from 10 to 300 parts by weight, based on 100 parts by weight of the total weight of the cyanate resin (A) and the epoxy resin (B) with a structure of formula (I).

25. The cyanate resin composition as claimed in claim 1, characterized in that the cyanate resin composition further comprises an organic filler (D).

26. The cyanate resin composition as claimed in claim 25, characterized in that the organic filler (D) is any one or a mixture of at least two selected from the group consisting of organosilicon, liquid crystal polymer, thermosetting resin, thermoplastic resin, rubber and core-shell rubber.

27. The cyanate resin composition as claimed in claim 25, characterized in that the organic filler (D) is in an amount of from 1 to 30 parts by weight, based on 100 parts by weight of the total weight of the cyanate resin (A) and the epoxy resin (B) with a structure of formula (I).

28. A prepreg, characterized in that the prepreg comprises a substrate material and the cyanate resin composition as claimed in claim 1 attached on the substrate material after impregnation and drying.

29. A laminate, characterized in that the laminate comprises at least one prepreg as claimed in claim 28.
